(19) United States
(12) Patent Application Publication
(10) Pub. No.: US 2019/0287935 A1
(43) Pub. Date: Sep. 19, 2019

(54) ULTRA LOW LOSS MICROELECTRONIC DEVICES HAVING INSULATING SUBSTRATES WITH OPTIONAL AIR CAVITY STRUCTURES

(71) Applicant: Intel Corporation, Santa Clara, CA (US)

(72) Inventors: Paul B. FISCHER, Portland, OR (US); Han Wui THEN, Portland, OR (US); Marko RADOSAVLJEVIC, Portland, OR (US); Sansaptak DASGUPTA, Hillsboro, OR (US)

(21) Appl. No.: 16/345,627

(22) PCT Filed: Dec. 21, 2016
(86) PCT No.: PCT/US2016/068068

§ 371 Date: Apr. 26, 2019

(51) Int. Cl. H01L 23/66; H01L 23/14; H01L 23/13; H01L 23/522; H01L 21/50

(52) U.S. Cl. CPC H01L 23/66; H01L 23/14; H01L 2223/6683; H01L 23/5227; H01L 21/50; H01L 23/13

(57) ABSTRACT

Embodiments of the invention include a microelectronic device that includes an insulating substrate, a RF transistor layer, and an interconnect structure disposed on the RF transistor layer. The RF transistor layer includes RF transistors for microwave frequencies. The interconnect structure includes at least one layer of dielectric material and a conductive layer having a plurality of conductive lines. The insulating substrate reduces parasitic capacitances and parasitic coupling to the insulating substrate.

### FIELD OF THE INVENTION

Embodiments of the present invention relate generally to the manufacture of semiconductor devices. In particular, embodiments of the present invention relate to microelectronic devices having insulating substrates with optional air cavity structures for ultra low loss monolithic microwave integrated circuits (MMIC).

### BACKGROUND OF THE INVENTION

The current state of the art for semiconductor material includes non-insulating silicon (Si) substrates in semiconductor manufacturing. However, eddy current losses result in loss of Q-factor for passives such as inductors and metal insulator metal (MIM) capacitors. Also, RF power loss in RF transistors as a result of coupling to a non-insulating Si substrates causes a loss of power-added efficiencies. These loss mechanisms in MMIC contribute to inefficiencies, excessive heat generation, and loss of battery life.

### BRIEF DESCRIPTION OF THE DRAWINGS

FIG. 1 illustrates a microelectronic device having an insulating substrate in accordance with one embodiment to reduce parasitic capacitances and parasitic coupling to the insulating substrate.

FIG. 2 illustrates a microelectronic device having an insulating substrate and an air cavity structure in accordance with one embodiment to reduce parasitic capacitances and parasitic coupling to the insulating substrate.

FIGS. 3A-3E illustrate a process for fabricating microelectronic devices having insulating substrates for reduced parasitic capacitances in accordance with one embodiment.

FIG. 4 illustrates a computing device 900 in accordance with one embodiment of the invention.

### DETAILED DESCRIPTION OF THE INVENTION

Described herein are microelectronic devices having insulating substrates with optional air cavity structures for ultra low loss monolithic microwave integrated circuits (MMIC). In the following description, various aspects of the illustrative implementations will be described using terms commonly employed by those skilled in the art to convey the substance of their work to others skilled in the art. However, it will be apparent to those skilled in the art that embodiments of the present invention may be practiced with only some of the described aspects. For purposes of explanation, specific numbers, materials and configurations are set forth in order to provide a thorough understanding of the illustrative implementations. However, it will be apparent to one skilled in the art that embodiments of the present invention may be practiced without the specific details. In other instances, well-known features are omitted or simplified in order to not obscure the illustrative implementations.

Various operations will be described as multiple discrete operations, in turn, in a manner that is most helpful in understanding embodiments of the present invention, however, the order of description should not be construed to imply that these operations are necessarily order dependent. In particular, these operations need not be performed in the order of presentation.

Electronic connections between the electronic devices (e.g., transistors) in an integrated circuit (IC) chip are currently typically created using copper metal or alloys of copper metal. Devices in an IC chip can be placed not only across the surface of the IC chip but devices can also be stacked in a plurality of layers on the IC chip. Electrical interconnections between electronic devices that make up the IC chip are built using vias and trenches that are filled with conducting material. Layer(s) of insulating materials, frequently, low-k dielectric materials, separate the various components and devices in the IC chip. The substrate on which the devices of the IC circuit chip are built is, for example, an insulating substrate (e.g., quartz) for embodiments of the present design.

At least one dielectric layer is deposited on the substrate. Dielectric materials include, but are not limited to, silicon dioxide (SiO2), low-k dielectrics, silicon nitrides, and or silicon oxynitrides. The dielectric layer optionally includes pores or other voids to further reduce its dielectric constant. Typically, low-k films are considered to be any film with a dielectric constant smaller than that of SiO₂ which has a dielectric constant of about 4.0. Low-k films having dielectric constants of about 1 to about 4.0 are typical of current semiconductor fabrication processes. The production of integrated circuit device structures often also includes placing a silicon dioxide film or layer, or capping layer on the surface of low-k (low dielectric constant) ILD (inter-layer dielectric) films. Low-k films can be, for example, boron, phosphorous, or carbon doped silicon oxides. Carbon-doped silicon oxides can also be referred to as carbon-doped oxides (CDOs) and organo-silicate glasses (OSGs).

To form electrical interconnects, dielectric layers are patterned to create one or more trenches and or vias within which metal interconnects will be formed. The terms trenches and vias are used herein because these are the terms commonly associated with the features that are used to form metal interconnects. In general, a feature used to form a metal interconnect is a depression having any shape formed in a substrate or layer deposited on the substrate. The feature is filled with conducting interconnect material. The trenches and or vias may be patterned (created) using conventional wet or dry etch semiconductor processing techniques. Dielectric materials are used to isolate electrically metal interconnects from the surrounding components.

Due to loss mechanisms for a conventional non-insulating substrate (e.g., a Si substrate having a resistivity of 1 kOhm/cm) the present design utilizes layer transfer techniques to provide an insulating substrate (e.g., quartz substrate, a substrate having a resistivity of significantly more than 10 kOhm/cm, BN substrate, Alumina substrate, Aluminum Nitride substrate, etc.) and optional air cavity structure to eliminate these loss mechanisms that result from non-insulating substrates. In one example, the present design provides reduced or minimal parasitic capacitances and reduced or minimal parasitic coupling to the substrate.

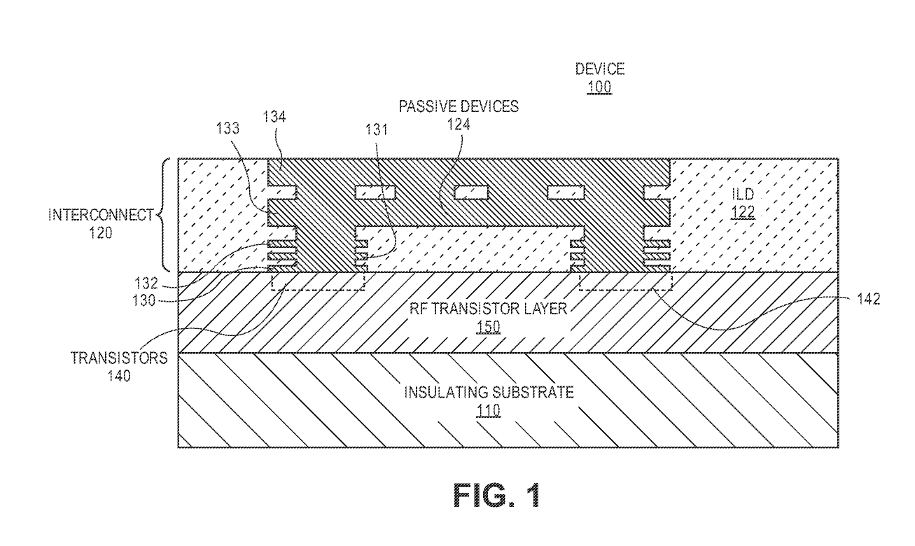

FIG. 1 illustrates a microelectronic device having an insulating substrate in accordance with one embodiment to reduce parasitic capacitances and parasitic coupling to the insulating substrate. The device 100 includes an insulating substrate 110 (e.g., quartz substrate, a substrate having a resistivity of significantly more than 10 kOhm cm, Boron Nitride substrate, Alumina substrate, Aluminum Nitride substrate, etc.) and an interconnect structure 120 having dielectric layer(s) 122 (e.g., ILD 122) for electrical isolation between conductive metal structures or lines 130-134 of the interconnect structure. Passive devices 124 may be formed with the metal structures or lines. RF transistors 140 and 142 are formed in active regions of the transistor layer 150. The RF transistors may be designed for monolithic microwave (e.g., frequency range of 300 MHz to 300 GHz) integrated circuits. The RF transistors may be designed in the RF transistor layer 150 that includes one or more layers (e.g., silicon, germanium, gallium arsenide, gallium nitride, or other Group III-V materials). The insulating substrate 110 may have a thickness of up to 750 microns.

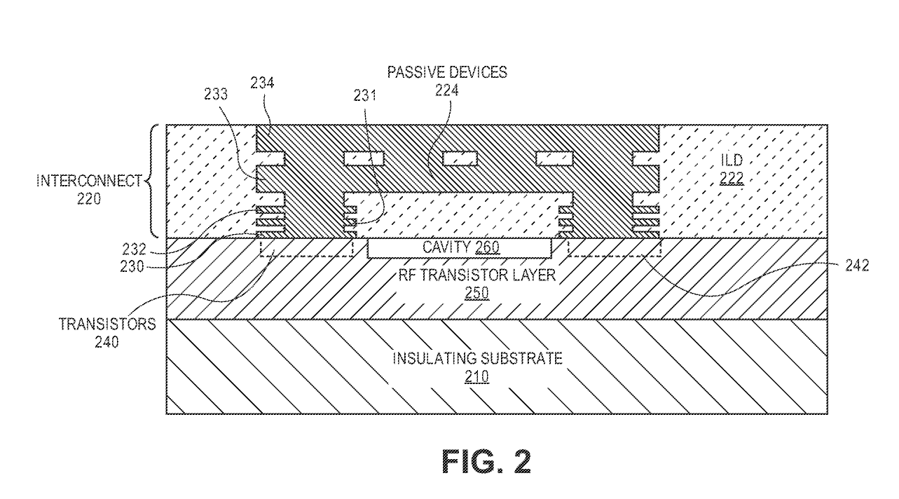

FIG. 2 illustrates a microelectronic device having an insulating substrate and an air cavity structure in accordance with one embodiment to reduce parasitic capacitances and parasitic coupling to the insulating substrate. The device 200 includes an insulating substrate 210 (e.g., quartz substrate, a substrate having a resistivity of significantly more than 10 kOhm/cm, BN substrate, Alumina substrate, Aluminum Nitride substrate, etc.) and an interconnect structure 220 having dielectric layer(s) 222 (e.g., ILD 222) for electrical isolation between conductive metal structures or lines 230-234 of the interconnect structure. Passive devices 224 may be formed with the metal structures or lines. RF transistors 240 and 242 are formed in active regions of the transistor layer 250. The RF transistors may be designed for monolithic microwave (e.g., frequency range of 300 MHz to 300 GHz) integrated circuits. The RF transistors may be designed in the RF transistor layer 250 that includes one or more layers (e.g,. silicon, germanium, gallium arsenide, gallium nitride, or other Group III-V materials). The insulating substrate 210 may have a thickness of up to 750 microns. An air cavity structure 260 is integrated with the RF transistor layer 250 to reduce parasitic capacitances and parasitic coupling to the insulating substrate. The air cavity structure 260 can have a minimum thickness of approximately 10 nanometers and a maximum thickness that is similar to a thickness of the substrate 210.

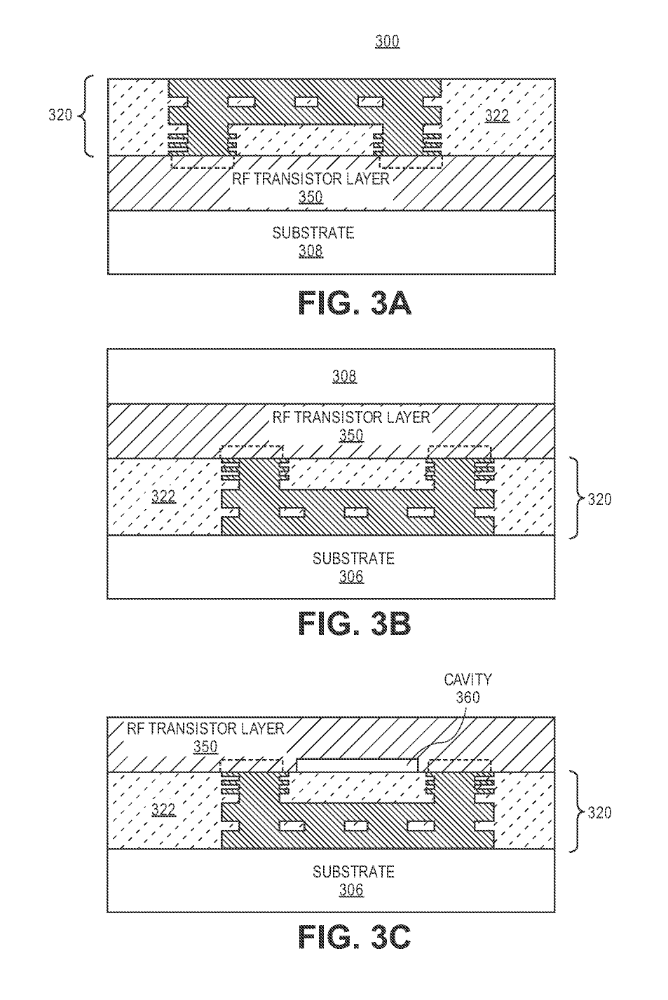

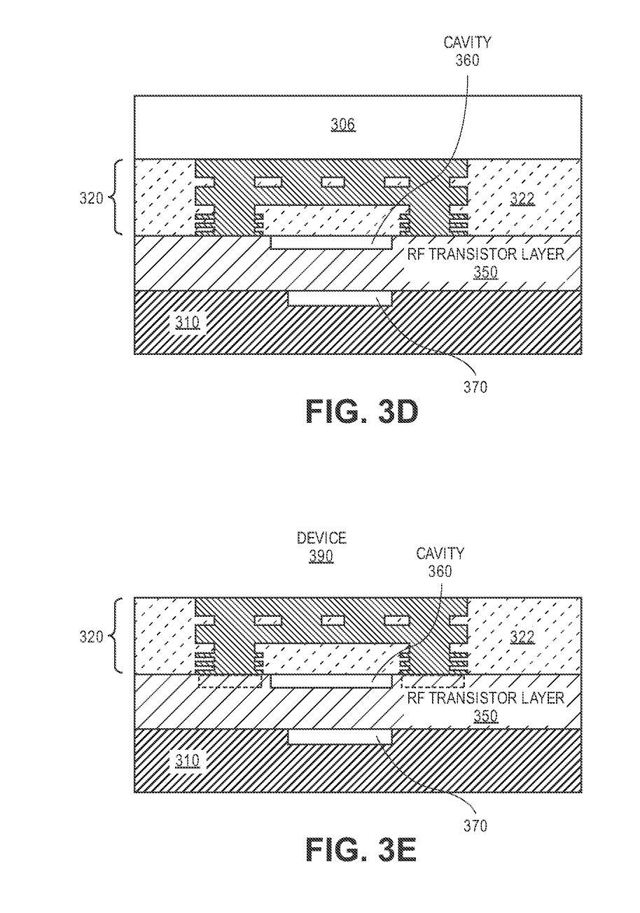

FIGS. 3A-3E illustrate a process for fabricating microelectronic devices having insulating substrates for reduced parasitic capacitances in accordance with one embodiment. In FIG. 3A, a microelectronic device 300 is fabricated on a non-insulating substrate 308 (e.g., Si substrate, a substrate having a resistivity of approximately 1 kOhm/cm). The interconnect structure 320 having dielectric layer(s) 322 (e.g., ILD 322) for electrical isolation between conductive metal structures or lines of the interconnect structure are similar to the interconnect structure 120 and 220 of FIGS. 1 and 2. Passive devices may be formed with the metal structures or lines. RF transistors are formed in active regions of the transistor layer 350, which is similar to the transistors layers 150 and 250 of FIGS. 1 and 2. The RF transistors may be designed for monolithic microwave (e.g., frequency range of 300 MHz to 300 GHz) integrated circuits. The RF transistors may be designed in the RF transistor layer 350 that includes one or more layers (e.g,. silicon, germanium, gallium arsenide, gallium nitride, or other Group III-V materials).

FIG. 3B illustrates a non-insulating substrate 306 being bonded (e.g., oxide fusion) to an upper surface of the interconnect 320 of the microelectronic device 300.

FIG. 3C illustrates the non-insulating substrate 308 being removed from the microelectronic device 300. In one example, the non-insulating substrate 308 is removed by grinding and polishing of the substrate 308 to expose an upper surface of the transistor layer 350 that has a surface root mean square (rms) of less than 1 nanometer after removal of the substrate 308. An upper surface of the transistor layer may have a surface topology of tens of nanometers across a region of the transistor layer. An air cavity 360 can also be formed in the transistor layer 350. The air cavity may be formed in an earlier stage of the process (e.g., during formation of the RF transistor layer 350).

FIG. 3D illustrates an insulating substrate 310 being bonded to a lower surface of the transistor layer 350. The insulating substrate 310 may optionally include an air cavity structure 370 or pre-recessed region of the insulating substrate 310.

FIG. 3E illustrates the non-insulating substrate 306 being removed from the microelectronic device 300 to form a microelectronic device 390. In one example, the non- insulating substrate 306 is removed by grinding and polishing of the substrate 306 to expose an upper surface of the interconnect 320 after removal of the substrate 306.

It will be appreciated that, in a system on a chip embodiment, a die may include a processor, memory, communications circuitry and the like. Though a single die is illustrated, there may be none, one or several dies included in the same region of the wafer.

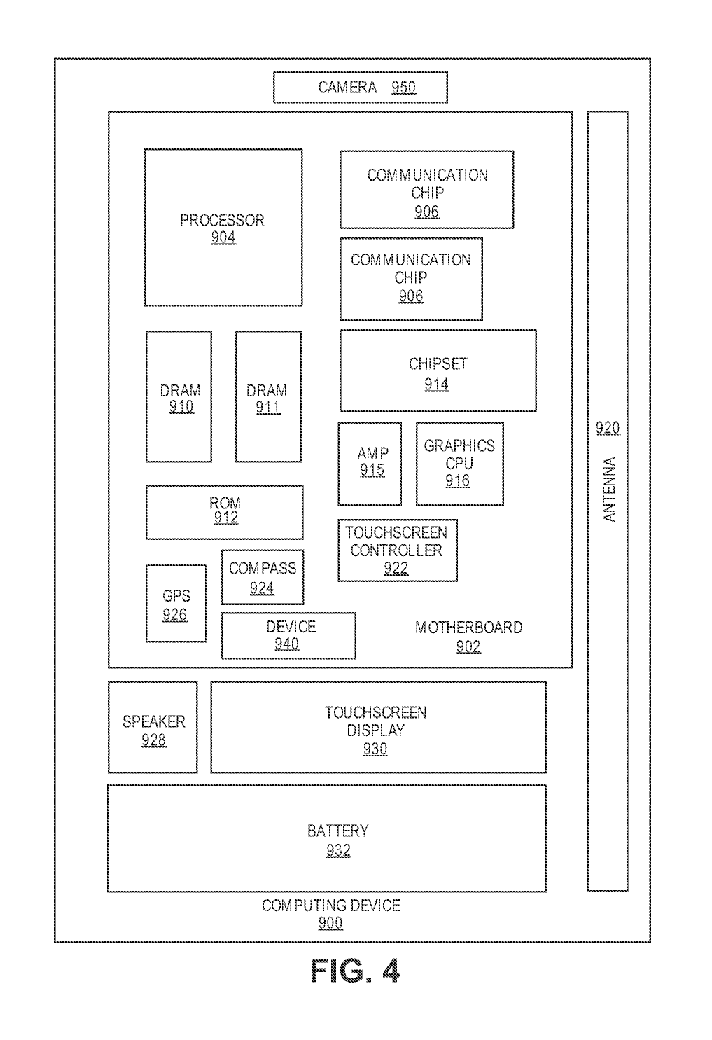

FIG. 4 illustrates a computing device 900 in accordance with one embodiment of the invention. The computing device 900 houses a board 902. The board 902 may include a number of components, including but not limited to at least one processor 904 and at least one communication chip 906. The at least one processor 904 is physically and electrically coupled to the board 902. In some implementations, the at least one communication chip 906 is also physically and electrically coupled to the board 902. In further implementations, the communication chip 906 is part of the processor 904. In one example, any of the components of the computing device include at least one microelectronic device (e.g., microelectronic device 100, 200, 390) having insulating substrates with optional integrated air cavity structures (e.g., air cavity structure 260, 360, 370). The computing device 900 may also include a separate microelectronic device 940 (e.g., microelectronic device 100, 200, 390).

Depending on its applications, computing device 900 may include other components that may or may not be physically and electrically coupled to the board 902. These other components include, but are not limited to, volatile memory (e.g., DRAM 910, 911), non-volatile memory (e.g., ROM 912), flash memory, a graphics processor 916, a digital signal processor, a crypto processor, a chipset 914, an antenna unit 920, a display, a touchscreen display 930, a touchscreen controller 922, a battery 932, an audio codec, a video codec, a power amplifier 915, a global positioning system (GPS) device 926, a compass 924, a gyroscope, a speaker, a camera 950, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), WiGig, IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi, WiGig, and Bluetooth and a second communication chip 906 may be dedicated to longer range wireless communications such as GPS, EDGE, GPRS, CDMA, WiMAX, LTE, Ev-DO, 5G, and others.

The at least one processor 904 of the computing device 900 includes an integrated circuit die packaged within the at least one processor 904. In some implementations of embodiments of the invention, the integrated circuit die of the processor includes one or more devices, such as microelectronic devices (e.g., microelectronic device 100, 200, 390, etc.) in accordance with implementations of embodiments of the invention. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of embodiments of the invention, the integrated circuit die of the communication chip includes one or more microelectronic devices (e.g., microelectronic device 100, 200, 390, etc.).

The following examples pertain to further embodiments. Example 1 is a microelectronic device that includes an insulating substrate, a RF transistor layer disposed on the insulating substrate with the RF transistor layer including RF transistors for microwave frequencies and an interconnect structure disposed on the RF transistor layer. The interconnect structure includes at least one layer of dielectric material and a conductive layer having a plurality of conductive lines. The insulating substrate to reduce parasitic capacitances and parasitic coupling to the insulating substrate.

In example 2, the subject matter of example 1 can optionally include the microelectronic device comprising a monolithic microwave integrated circuit.

In example 3, the subject matter of any of examples 1-2 can optionally include the insulating substrate comprising a quartz substrate.

In example 4, the subject matter of any of examples 1-3 can optionally include the insulating substrate comprising a Boron Nitride substrate, an Alumina substrate, or an Aluminum Nitride substrate.

In example 5, the subject matter of any of examples 1-4 can optionally include the insulating substrate has a resistivity that is significantly greater than 10 kilo ohm centimeters.

In example 6, the subject matter of any of examples 1-5 can optionally include the insulating substrate comprises an air cavity structure that is located in proximity to a lower surface of the RF transistor layer.

In example 7, the subject matter of any of examples 1-6 can optionally include the air cavity structure having a dielectric constant of approximately 1.0.

In example 8, the subject matter of any of examples 1-7 can optionally include the conductive layer comprising low loss inductors.

Example 9 is a microelectronic device comprising an insulating substrate, a RF transistor layer disposed on the insulating substrate, and an interconnect structure disposed on the RF transistor layer. The interconnect structure includes at least one layer of dielectric material and a conductive layer having a plurality of conductive lines, and an air cavity structure that is integrated with the insulating substrate to reduce parasitic capacitances and parasitic coupling to the insulating substrate.

In example 10, the subject matter of example 9 can optionally include the microelectronic device comprising a monolithic microwave integrated circuit.

In example 11, the subject matter of any of examples 9-10 can optionally include the insulating substrate comprising a quartz substrate.

In example 12, the subject matter of any of examples 9-11 can optionally include the insulating substrate comprising a Boron Nitride substrate, an Alumina substrate, or an Aluminum Nitride substrate.

In example 13, the subject matter of any of examples 9-12 can optionally include the insulating substrate having a resistivity that is significantly greater than 10 kilo ohm centimeters.

In example 14, the subject matter of any of examples 9-13 can optionally include the air cavity structure being located in proximity to a lower surface of the RF transistor layer.

In example 15, the subject matter of any of examples 9-14 can optionally include an additional air cavity structure that is integrated with the RF transistor layer in proximity to the interconnect structure.

In example 16, the subject matter of any of examples 9-15 can optionally include the conductive layer comprising low loss inductors.

Example 17 is a method comprising forming a RF transistor layer of a microelectronic device with the RF transistor layer including RF transistors for microwave frequencies and forming an interconnect structure on an upper surface of the RF transistor layer. The interconnect structure includes at least one layer of dielectric material and a conductive layer having a plurality of conductive lines. The method further includes bonding an insulating substrate to a lower surface of the RF transistor layer.

In example 18, the subject matter of example 17 can optionally include the microelectronic device comprising a monolithic microwave integrated circuit.

In example 19, the subject matter of any of examples 17-18 can optionally include the insulating substrate comprising a quartz substrate, a Boron Nitride substrate, an Alumina substrate, or an Aluminum Nitride substrate.

In example 20, the subject matter of any of examples 17-19 can optionally include the insulating substrate having a resistivity that is significantly greater than 10 kilo ohm centimeters.

1. A microelectronic device comprising:
an insulating substrate;
a RF transistor layer disposed on the insulating substrate with the RF transistor layer including RF transistors for microwave frequencies; and
an interconnect structure disposed on the RF transistor layer, the interconnect structure includes at least one layer of dielectric material and a conductive layer having a plurality of conductive lines, the insulating substrate to reduce parasitic capacitances and parasitic coupling to the insulating substrate.

2. The microelectronic device of claim 1, wherein the microelectronic device comprises a monolithic microwave integrated circuit.

3. The microelectronic device of claim 1, wherein the insulating substrate comprises a quartz substrate.

4. The microelectronic device of claim 1, wherein the insulating substrate comprises a Boron Nitride substrate, an Alumina substrate, or an Aluminum Nitride substrate.

5. The microelectronic device of claim 1, wherein the insulating substrate has a resistivity that is significantly greater than 10 kilo ohm centimeters.

6. The microelectronic device of claim 1, wherein the insulating substrate comprises an air cavity structure that is located in proximity to a lower surface of the RF transistor layer.

7. The microelectronic device of claim 6 wherein the air cavity structure has a dielectric constant of approximately 1.0.

8. The microelectronic device of claim 1 wherein the conductive layer comprises low loss inductors.

9. A microelectronic device comprising:
an insulating substrate;
a RF transistor layer disposed on the insulating substrate;
an interconnect structure disposed on the RF transistor layer, the interconnect structure includes at least one layer of dielectric material and a conductive layer having a plurality of conductive lines; and
an air cavity structure that is integrated with the insulating substrate to reduce parasitic capacitances and parasitic coupling to the insulating substrate.

10. The microelectronic device of claim 9, wherein the microelectronic device comprises a monolithic microwave integrated circuit.

11. The microelectronic device of claim 9, wherein the insulating substrate comprises a quartz substrate.

12. The microelectronic device of claim 9, wherein the insulating substrate comprises a Boron Nitride substrate, an Alumina substrate, or an Aluminum Nitride substrate.

13. The microelectronic device of claim 9, wherein the insulating substrate has a resistivity that is significantly greater than 10 kilo ohm centimeters.

14. The microelectronic device of claim 9, wherein the air cavity structure is located in proximity to a lower surface of the RF transistor layer.

15. The microelectronic device of claim 9 further comprising an additional air cavity structure that is integrated with the RF transistor layer in proximity to the interconnect structure.

16. The microelectronic device of claim 9 wherein the conductive layer comprises low loss inductors.

17. A method comprising:
forming a RF transistor layer of a microelectronic device with the RF transistor layer including RF transistors for microwave frequencies;
forming an interconnect structure on an upper surface of the RF transistor layer, the interconnect structure includes at least one layer of dielectric material and a conductive layer having a plurality of conductive lines; and
bonding an insulating substrate to a lower surface of the RF transistor layer.

18. The method of claim 17, wherein the microelectronic device comprises a monolithic microwave integrated circuit.

19. The method of claim 17, wherein the insulating substrate comprises a quartz substrate, a Boron Nitride substrate, an Alumina substrate, or an Aluminum Nitride substrate.

20. The method of claim 17, wherein the insulating substrate has a resistivity that is significantly greater than 10 kilo ohm centimeters.
